(19) United States
(12) Patent Application Publication
(10) Pub. No.: US 2016/0336366 A1
(43) Pub. Date: Nov. 17, 2016

(54) LIGHT-RECEIVING DEVICE AND MANUFACTURING METHOD THEREOF

(71) Applicant: Panasonic Intellectual Property Management Co., Ltd., Osaka (JP)

(72) Inventor: SHIGEFUMI DOHI, Kanagawa (JP)

(21) Appl. No.: 15/218,213

(22) Filed: Jul. 25, 2016

Related U.S. Application Data
(63) Continuation of application No. PCT/JP2015/000654, filed on Feb. 13, 2015.

(30) Foreign Application Priority Data
Feb. 19, 2014 (JP) 2014-029219

(51) Int. Cl. H01L 27/146

(52) U.S. Cl. CPC H01L 27/14623; H01L 27/14634

(57) ABSTRACT

A light-receiving device which has high reliability and high sensitivity is provided with low cost. The device has a laminate type device structure in which a photoelectric converter and a scanning circuit unit are connected by microbumps, and a structure in which a transparent conductive film is formed on a photodiode of a photoelectric converter. A rewiring is formed so as to have a function of an OB region, and an electrode for supplying a voltage to a scanning circuit and the photodiode on the transparent conductive film, and the rewiring is electrically connected to an external electrode by a wire.

### BACKGROUND

1. Technical Field

The present disclosure relates to a light-receiving device which converts incident light into an electric signal, particularly, to a light-receiving device in which semiconductor scanning circuits, which read a signal of electrical charge converted from incident light using a photodiode having a photoelectric conversion function, are laminated, and a manufacturing method thereof.

2. Description of the Related Art

As a light-receiving device of the related art, a light-receiving device in which a photodiode of a photoelectric converter and a scanning element transmitting photocharge generated by the photodiode are integrated on a semiconductor substrate, is developed and is commercially used.

In the light-receiving device having such a structure, since the photodiode and the scanning element are disposed on the same plan surface, an aperture ratio (ratio of amount of light incident on photoelectric converter with respect to amount of light incident on light receiving surface) is low and a light utilization rate is low, and thus a loss of incident light is great.

An actual aperture ratio is improved when on-chip microlenses are developed, and the like; however, there is a limit that the actual aperture ratio is improved, as long as the photodiode and the scanning element are disposed on the same plan surface.

Here, a light-receiving device having a structure, in which photodiodes generating the photocharge are laminated on an upper portion of a circuit substrate for transmitting the photocharge, is proposed.

In such a structure, the entirety of a light receiving surface is a photodiode, and thus the aperture ratio can reach substantially 100% and sensitivity can be improved.

In the light-receiving device, since generally good light response properties are realized, a structure in which electrodes which are in contact with a photodiode in order to inhibit injecting of electrical charge are used is adopted.

Therefore, a signal electrical charge equal to or more than the number of carriers generated due to incident light cannot be ejected outside an element in which electrical charge multiplication is not used inside the element, and a gain of photoelectric conversion is one or less.

In contrast, as a light-receiving device in which the gain of photoelectric conversion exceeds one, an avalanche multiplication type light-receiving device, in which an avalanche multiplication phenomenon is generated by applying a strong electric field to a photodiode and the gain of photoelectric conversion is equal to or more than one, is developed.

In such an avalanche multiplication type light-receiving device, gains in a ratio of the number of photocharge generated inside the photodiode with respect to the number of incident photons are several tens to hundreds.

The above described laminate type light-receiving device is formed by forming a scanning circuit on a silicon substrate in a semiconductor process used for a general integrated circuit, and sequentially laminating the photodiode and a transparent conductive film thereon.

In this case, since the scanning circuit before forming the transparent conductive film is formed on the silicon substrate through a complicated process, a surface thereof is less likely to be smooth, and unevenness exists on the pixel electrode itself or a boundary of the pixel electrode.

Therefore, for example, unlike a case of a photoconductive type image pick-up tube of which a photoconductive film is formed on a smooth glass substrate, there is a problem in that dark current is increased by a local electric field concentration caused by the unevenness of a base and a defect of white dots on a screen is likely to be generated.

Particularly, in a case in which high sensitivity is obtained using the avalanche multiplication phenomenon in the photodiode, it is necessary that a strong electric field is applied to the photodiode, and thus injecting of a local dark current or an avalanche breakdown due to non-uniformity of the electric field is likely to be generated.

As a technology of the related art for solving the above described problem, there is a technology in which a photoelectric converter configured with a transparent conductive film and a photodiode which are formed on a light transmitting substrate as in PTL 1, is connected to an electrode which reads out a signal of a scanning circuit formed on a substrate separated from the above described light transmitting substrate through conductive microbumps.

FIG. 9 is a sectional view of a photoelectric converter of the light-receiving device of the related art, and after transparent conductive film 103 and photodiode 104 are formed on light transmitting substrate 115, first pixel electrode 105 is formed so as to be arranged having voids and a predetermined size on a surface. On a surface of scanning circuit 108, second pixel electrode 107 having the same pitch as that of first pixel electrode 105 is provided, and on second pixel electrode 107, microbumps 106 for electrically connecting to photoelectric converter 101 and scanning circuit unit 102 are formed.

The light-receiving device of the related art has a structure in which photoelectric converter 101 and scanning circuit unit 102, which are formed separately as the above description, are electrically connected to each other by microbumps 106 as illustrated in FIG. 9.

In the related art, for example, using a substrate which is sufficiently grinded to be flat, photodiode 104 is formed on a very flat base.

Accordingly, for example, even when the device is operated by applying a high electric field so as to cause electrical charge multiplication due to the avalanche phenomenon in the photodiode, an increase of the dark current due to the local electric field concentration or avalanche breakdown is less likely to be generated.

In addition, since scanning circuit unit 102 and photoelectric converter 101 are separately manufactured, a material can be selected without considering electrical bonding properties of second pixel electrode 107 and photodiode 104 on scanning circuit 108.

That is, the optimum material or a structure, and a manufacturing method can be adopted without limitation for making a laminate type imaging device.

Therefore, as an advantage of a laminate structure using such microbumps, for example, as a substrate constituting a photodiode, a silicon on insulator (SOI) substrate is used. After the scanning circuit and microbumps are laminated, a transparent conductive film is formed by removing silicon and silicon dioxide film, and thus properties of the photodiode are further improved. The SOI substrate is a substrate having a structure in which a silicon dioxide film is inserted between a silicon substrate reducing a parasitic capacitance of a transistor and effective in improving an operation speed and reducing power consumption and a surface silicon layer (refer to PTL 1 and PTL 2).

### CITATION LIST

### Patent Literature

PTL 1: Japanese Patent Unexamined Publication No. 7-192663

PTL 2: Japanese Patent Unexamined Publication No. 9-82932

### SUMMARY

However, in a structure of the related art, in a case in which an optical black (OB) region regulating a level of “black” of a pixel value is formed like a general light-receiving device, a light shielding film is required to be formed on an upper surface of a photodiode.

Therefore, it is necessary that the light shielding film is formed before forming the photodiode or is specially formed on an upper surface of the photodiode after laminating the photodiode and a scanning circuit by microbumps.

However, when an SOI substrate is used as a substrate for improving properties of the photodiode, the light shielding film cannot be formed before forming the photodiode because of its structure.

After laminating the photodiode and the scanning circuit by microbumps, if the light shielding film is formed on the upper surface of the photodiode, a special process for forming the light shielding film increases, and thus there is a problem in that productivity and producing costs increase.

Also, for example, in a case in which a high electric field is applied to operate the device so as to cause electrical charge multiplication due to an avalanche phenomenon in the photodiode, a voltage is required to be supplied to a transparent conductive film on the photodiode.

As a method of supplying the voltage, for example, there is a method in which a wire is connected to the transparent conductive film on the photodiode as illustrated in FIG. 10 (PTL 2).

However, in the method described above, there is a very high risk that the photodiode is broken or properties thereof are deteriorated due to a stress at the time of connecting the wire with the transparent conductive film.

Further, since a voltage is supplied to the photodiode through a thin transparent conductive film from the wire, supplying the voltage is unstable, and a desired electrical charge multiplication effect and a high sensitivity are less likely to be obtained.

In order to solve the above described problem, the light-receiving device of this disclosure includes a photoelectric converter, a scanning circuit unit connected by microbumps formed on a pixel electrode of a photoelectric converter, and a transparent conductive film formed on an upper surface of a photodiode of the photoelectric converter. The light-receiving device of this disclosure further includes wirings formed on the transparent conductive film and the photodiode and an external terminal connected to the wirings.

According to the light-receiving device of the disclosure, in a rewiring forming process after completing a laminating process, an OB region and a wire bonding electrode can be simultaneously formed, and thus a process which aims to form an OB region is not required to be specially provided, and a singular process of forming an OB region can be omitted.

In addition, since a wiring is not directly provided on the transparent conductive film on the photodiode, a risk of deterioration of properties of the photodiode or a damage of the photodiode due to stress at the time of providing the wiring can be reduced.

Also, since a voltage is supplied to the transparent conductive film using a rewiring of a thick film having low resistance, supplying of the voltage can be stabilized.

### BRIEF DESCRIPTION OF THE DRAWINGS

FIG. 1 is a sectional view of a light-receiving device according to a first exemplary embodiment of the disclosure;

FIG. 2 is a plan view of the light-receiving device according to the first exemplary embodiment of the disclosure;

FIG. 3A is a sectional view of a semiconductor device relating to a manufacturing method of the light-receiving device according to the first exemplary embodiment of the disclosure;

FIG. 3B is a sectional view of the semiconductor device relating to the manufacturing method of the light-receiving device according to the first exemplary embodiment of the disclosure;

FIG. 3C is a sectional view of the semiconductor device relating to the manufacturing method of the light-receiving device according to the first exemplary embodiment of the disclosure;

FIG. 3D is a sectional view of the semiconductor device relating to the manufacturing method of the light-receiving device according to the first exemplary embodiment of the disclosure;

FIG. 3E is a sectional view of the semiconductor device relating to the manufacturing method of the light-receiving device according to the first exemplary embodiment of the disclosure;

FIG. 3F is a sectional view of the semiconductor device relating to the manufacturing method of the light-receiving device according to the first exemplary embodiment of the disclosure;

FIG. 3G is a sectional view of the semiconductor device relating to the manufacturing method of the light-receiving device according to the first exemplary embodiment of the disclosure;

FIG. 4 is a sectional view of a light-receiving device according to a second exemplary embodiment of the disclosure;

FIG. 5 is a plan view of the light-receiving device according to the second exemplary embodiment of the disclosure;

FIG. GA is a sectional view of a semiconductor device relating to the manufacturing method of the light-receiving device according to the second exemplary embodiment of the disclosure;

FIG. 6B is a sectional view of the semiconductor device relating to the manufacturing method of the light-receiving device according to the second exemplary embodiment of the disclosure;

FIG. 6C is a sectional view of the semiconductor device relating to the manufacturing method of the light-receiving device according to the second exemplary embodiment of the disclosure;

FIG. 6D is a sectional view of the semiconductor device relating to the manufacturing method of the light-receiving device according to the second exemplary embodiment of the disclosure;

FIG. 6E is a sectional view of the semiconductor device relating to the manufacturing method of the light-receiving device according to the second exemplary embodiment of the disclosure;

FIG. 6F is a sectional view of the semiconductor device relating to the manufacturing method of the light-receiving device according to the second exemplary embodiment of the disclosure;

FIG. 6G is a sectional view of the semiconductor device relating to the manufacturing method of the light-receiving device according to the second exemplary embodiment of the disclosure;

FIG. 6H is a sectional view of the semiconductor device relating to the manufacturing method of the light-receiving device according to the second exemplary embodiment of the disclosure;

FIG. 6I is a sectional view of the semiconductor device relating to the manufacturing method of the light-receiving device according to the second exemplary embodiment of the disclosure;

FIG. 7 is a sectional view of a light-receiving device according to a third exemplary embodiment of the disclosure;

FIG. 8 is a plan view of the light-receiving device according to the third exemplary embodiment of the disclosure;

FIG. 9 is a sectional view of an imaging element according to the related art; and

FIG. 10 is a sectional view of a solid imaging element according to the related art.

### DETAILED DESCRIPTIONS

Hereinafter, exemplary embodiments of a device (referred to as disclosure) according to this disclosure will be described with reference to drawings.

### First Exemplary Embodiment

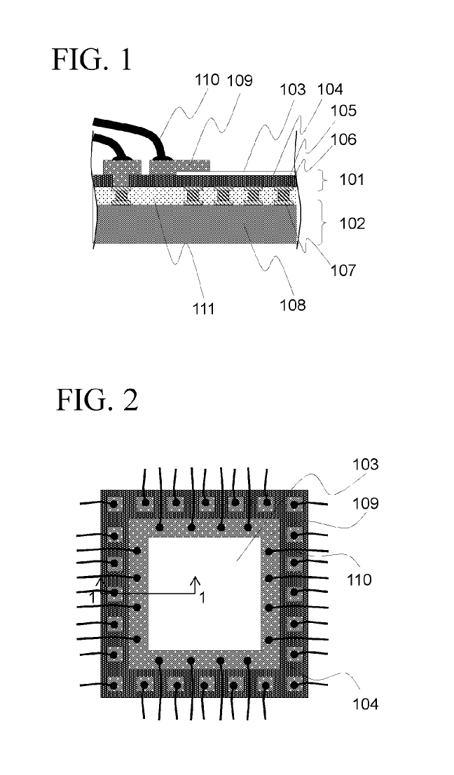

FIG. 1 is a sectional view of a light-receiving device according to a first exemplary embodiment of the disclosure. The light-receiving device is a laminate type device structure in which first pixel electrode 105 formed on photoelectric converter 101 and second pixel electrode 107 formed on scanning circuit unit 102 are connected to each other by microbump 106. Transparent conductive film 103 is formed on photodiode 104 of photoelectric converter 101. Rewiring 109 for supplying power to scanning circuit unit 102 and a photodiode is formed on transparent conductive film 103, and rewiring 109 is electrically connected to an external electrode by wire 110.

Peripheries of microbump 106 are covered with protection film 111, and rewiring 109 is formed directly on at least one of first pixel electrodes 105.

FIG. 2 is a top view of the light-receiving device according to the disclosure. A part of an upper surface of transparent conductive film 103 is covered with rewiring 109, and rewiring 109 is connected by wire 110.

Such a rewiring 109 is formed directly on a part of a pixel electrode so that light from the upper surface is shielded, and then an OB region can be formed.

In addition, since the wire is not directly bonded to transparent conductive film 103 on photodiode 104, a characteristic change or damage due to stress at the time of bonding the wires can be avoided.

As a material of rewiring 109, Cu, in which a wafer batching process can be performed by plating and a thick film equal to or more than 5 μm can be formed in a short time, can be used.

When a voltage is supplied to a photodiode with such a structure, a voltage drop due to a wiring resistance can be reduced, and thus supplying voltage is stabilized.

As the material of rewiring 109, Au which has a good wire bonding property, or a structure of Au and Ni or Au, Ni, and Cu from the upper surface is adopted, and thus the wire bonding property can be improved.

Protection film 111 may be an epoxy based or acryl based underfill resin, and may be an organic passivation such as PBO (polybenzoxazole) or PI (polyimide).

An inorganic passivation such as SiN (silicon nitride) may be used.

There are various known methods of manufacturing methods and materials of microbump 106, and a microbump by a plating method, a photolithograph method, or the like. In any method, it is important that bumps (protrusion electrode) having a height of several μm to several tens of vim corresponding to an electrode are formed on the electrode.

As a conductive material, resistance as low as possible is needed from a view point of required properties of the bumps. As a metal material constituting a conductive material, Sn, Cu, Au, Ni, Co, Pd, Ag, In, a plurality of layers of those materials, or an alloy of those materials are used.

As a conductive material, there is a paste type of which conductive particles are mixed with an adhesive, that is, a conductive paste. As a conductive paste, for example, there is Ag or an Ag-Pd paste. The Ag or Ag-Pd paste is printed onto a reading electrode, and microbump 106 may be formed.

Also, a metal having excellent malleability and adhesion, such as Au, In single body, or In alloy, is formed on the reading electrode in a column shape or a cone shape, and thus microbump 106 may be formed. When the metal having malleability and adhesion and a conductive paste are used concurrently, microbump 106 may be formed.

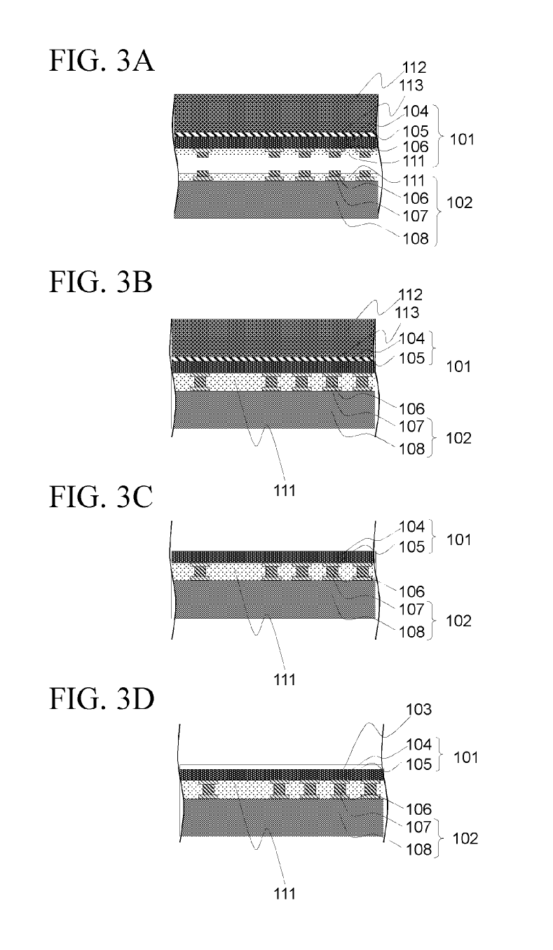

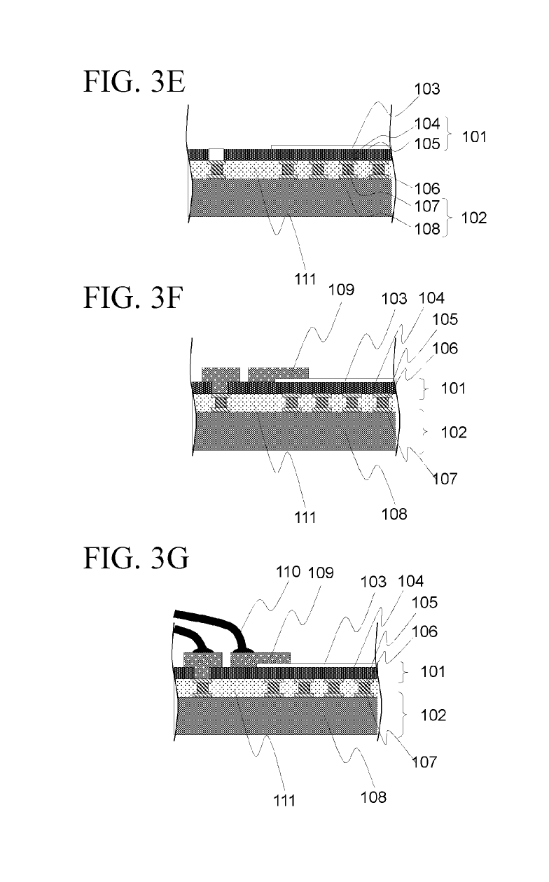

FIG. 3A to FIG. 3G are sectional views of the light-receiving device of relating to the manufacturing method of the light-receiving device according to a first exemplary embodiment of the disclosure.

As illustrated in FIG. 3A, first, there are silicon substrate 112, silicon dioxide film 113, photoelectric converter 101 constituted by photodiode 104 formed on silicon substrate 112 and silicon dioxide film 113, scanning circuit unit 102, and microbumps 106 formed on each pixel electrode thereof are aligned to be arranged at a desired position.

Next, as illustrated in FIG. 3B, the above described components are connected by making microbumps 106 come in contact with each other.

Next, as illustrated in FIG. 3C, silicon substrate 112 and silicon dioxide film 113 are removed by a wet method or a dry method, and photodiode 104 is exposed from the top.

Next, as illustrated in FIG. 3D, transparent conductive film 103 is formed on photodiode 104 by a vapor deposition method.

Next, as illustrated in FIG. 3E, unnecessary transparent conductive film 103 is removed by etching, and an electrode supplying a voltage to scanning circuit 108 is opened and exposed.

Next, as illustrated in FIG. 3F, rewiring 109 is formed by a photolithography method and a plating method.

Next, as illustrated in FIG. 3G, wire 110 is formed on rewiring.

Here, before forming a wire, an assembling process in consideration of a device state before bonding the wire and a structure of a final assembly, for example, a process such as back grinding of a wafer, dicing, the bonding, or wire bonding can be arbitrarily selected.

### Second Exemplary Embodiment

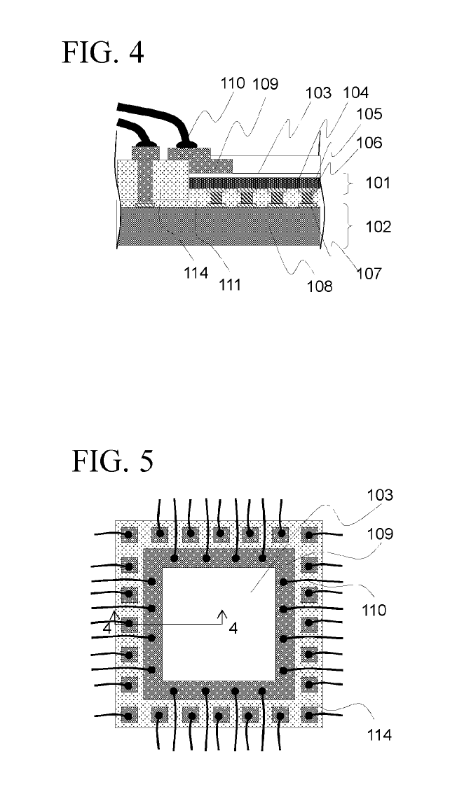

FIG. 4 is a sectional view of a light-receiving device according to a second exemplary embodiment of the disclosure, and FIG. 5 is a plan view.

Referring to FIG. 4 and FIG. 5, peripheries of photodiode 104 are covered with resin 114.

Rewiring 109 is formed on resin 114 and photodiode 104, and is electrically connected to an external electrode by wire 110.

As seen from the above, since the peripheries of photoelectric converter 101 are covered with resin 114 and a size of a plan of photoelectric converter 101 itself can be reduced, the number of devices mounted near the wafer is increased, and costs of the devices can be reduced.

Further, a restriction in which photoelectric converter 101 and scanning circuit unit 102 are made the same size can be released, and a degree of freedom in design of the device is significantly improved.

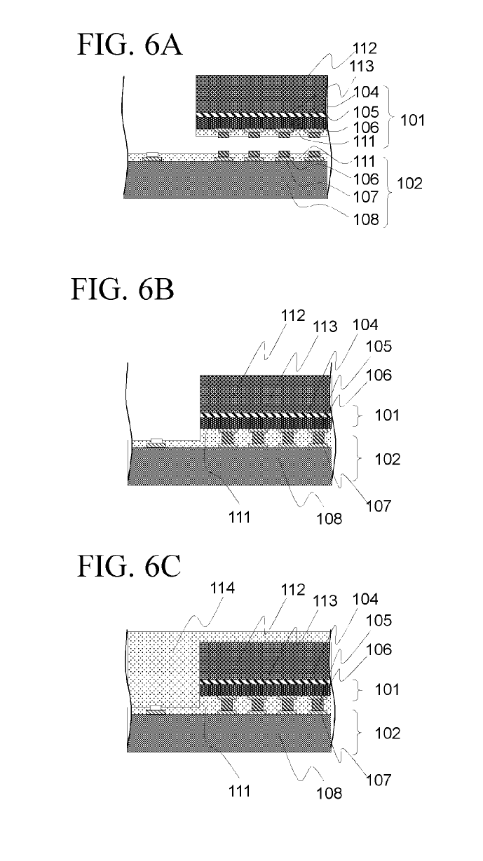

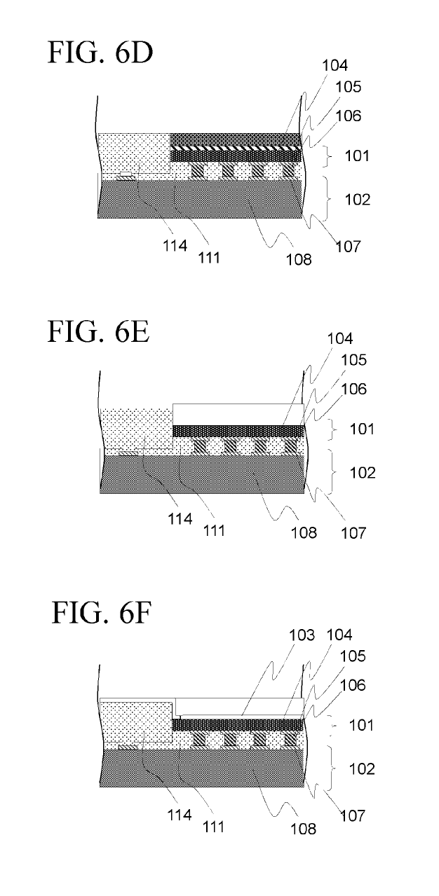

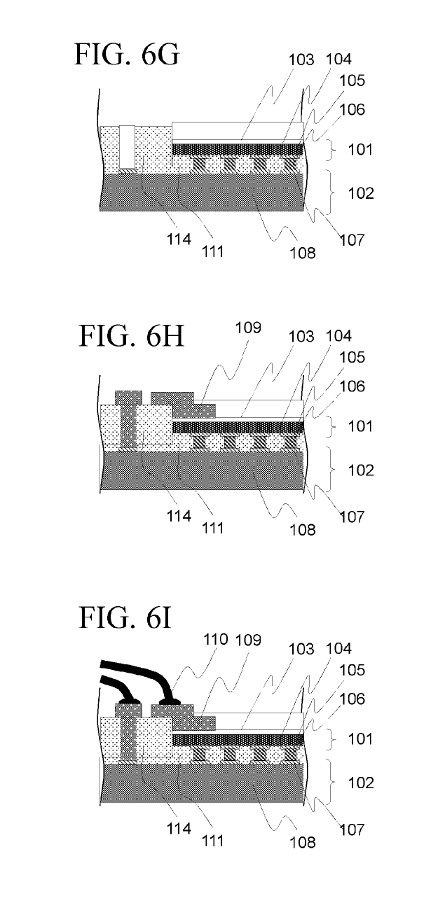

FIG. 6A to FIG. 6I are sectional views relating to a manufacturing method of the light-receiving device according to the second exemplary embodiment of the disclosure.

As illustrated in FIG. 6A, first, there are silicon substrate 112, silicon dioxide film 113, photoelectric converter 101 constituted by photodiode 104 formed on silicon substrate 112 and silicon dioxide film 113, scanning circuit unit 102, and microbumps 106 formed on each pixel electrode thereof are aligned to be arranged at a desired position.

Next, as illustrated in FIG. 6B, the above described components are connected by making microbumps 106 come in contact with each other.

Next, as illustrated in FIG. 6C, resin 114 is formed on a side surface and an upper surface of the photoelectric converter.

Next, as illustrated in FIG. 6D, resin 114 and silicon substrate 112 are grinded by back grinding.

Next, as illustrated in FIG. 6E, silicon substrate 112 and silicon dioxide film 113 are removed by etching.

Next, as illustrated in FIG. 6F, transparent conductive film 103 is formed on photodiode 104 and resin 114 by a vapor deposition method.

Next, as illustrated in FIG. 6G, transparent conductive film 103 on resin 114 is removed, and resin on an electrode of a scanning circuit unit is removed, and therefore, the electrode is opened.

Next, rewiring 109 is formed by photolithography and plating as illustrated in FIG. 6H.

Next, as illustrated in FIG. 6I, wire 110 is formed on rewiring.

Here, after a wire forming process, an assembling process in consideration of a device state before bonding the wire and a structure of a final assembly, for example, a process such as back grinding of a wafer, dicing, die bonding, or wire bonding can be arbitrarily selected.

### Third Exemplary Embodiment

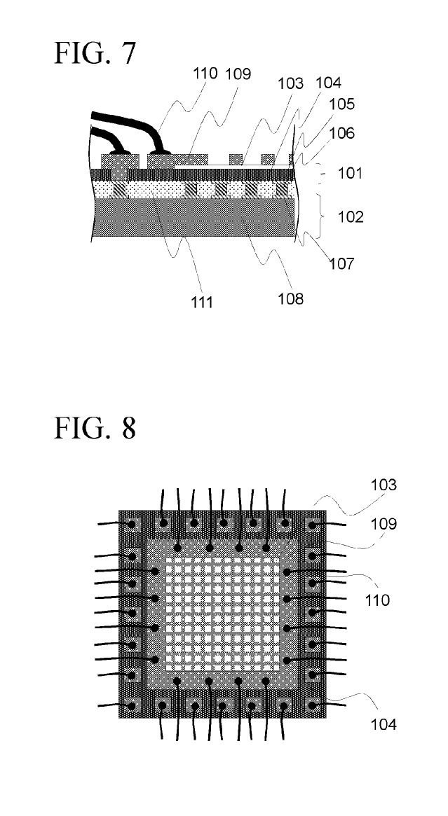

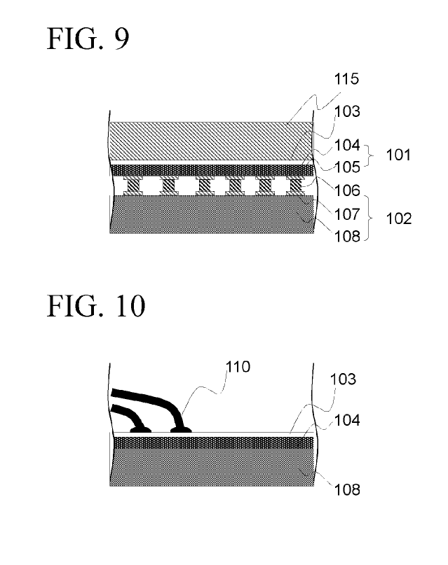

FIG. 7 is a sectional view of a light-receiving device according to a third exemplary embodiment of the disclosure, and FIG. 8 is a plan view thereof.

Referring to FIG. 7 and FIG. 8, rewiring 109 can be formed in a grid shape between pixel electrodes on an upper surface of transparent conductive film 103 of photodiode 104, so that the OB region is removed and incident light into pixel electrodes is not inhibited.

As described above, rewiring 109 on transparent conductive film 103 between pixel electrodes where the OB region is removed is wound in a grid shape, thereby making it possible to reduce dispersion of voltage applying due to a positional relationship of rewiring 109 and photodiode 104.

The disclosure is not limited to the exemplary embodiments described above, and there is a variety of other forms changed within a range in consideration of those skilled in the art with respect to the exemplary embodiments, and the like, without departing from the spirit of the disclosure.

In the exemplary embodiment described in FIG. 1, there is an example of which wire 110 is formed on rewiring 109 directly on an opening of a photodiode; however, the wire may not be formed directly on the opening

Therefore, since the wire is formed by removing a part directly above the opening, which has a low flatness of rewiring by relatively receiving an influence of an opening shape, wire bonding connectivity is improved.

In addition, rewiring 109, in which an electrode connected to scanning circuit unit 102 and an electrode connected to transparent conductive film 103 are completely separated from each other, is exemplified; however, it is not necessary to be completely separated.

Also, an example of which the peripheries of rewiring 109 are not covered with a protection film is exemplified in this example; however, in order to physically protect the wirings or to reduce a risk of electrical short-circuit between the wirings, a protection film may be formed and be used to protect the rewiring.

In the exemplary embodiments described in FIG. 3A and FIG. 6A, microbumps 106 formed in a photoelectric converter and a scanning circuit unit, which are protruded and exposed on the upper surface of protection film 111, are exemplified; however, it is not limited thereto, and the microbumps may be formed on the same surface as a protection film or may be caved-in.

In the exemplary embodiments described in FIG. 4, resin 114 which is exposed as a protrusion on an upper surface further than a photoelectric converter, is exemplified; however, it is not limited thereto, and resin 114 may be formed on an upper surface further than a photoelectric converter, or may be formed to be caved-in.

The disclosure can be appropriately used for, for example, a light-receiving device for which small, high performance, high sensitivity, and low costs are required.

What is claimed is:

1. A light-receiving device comprising:
a photoelectric converter;
a scanning circuit unit that is connected to the photoelectric converter by microbumps formed on a pixel electrode of the photoelectric converter;
a transparent conductive film that is formed on an upper surface of a photodiode of the photoelectric converter;
wirings that are formed on the transparent conductive film and the photodiode; and
an external terminal that is connected to the wirings.

2. The light-receiving device of claim 1,
wherein a region of the wirings on the photodiode is formed to be an optical black region as a light shielding film.

3. The light-receiving device of claim 1,
wherein the photodiode includes means which applies a voltage of a value which causes electrical charge multiplication action inside the photodiode.

4. The light-receiving device of claim 1,
wherein the wirings are formed in a grid shape between a plurality of the pixel electrodes.

5. The light-receiving device of claim 1,
wherein the wirings are rewirings.

6. A light-receiving device comprising:
a photoelectric converter;
a scanning circuit unit that is connected to the photoelectric converter by microbumps formed on a pixel electrode of the photoelectric converter;
a transparent conductive film that is formed on an upper surface of a photodiode of the photoelectric converter;
a resin that surrounds the photoelectric converter;
wirings that are formed on the resin, the transparent conductive film, and the photodiode; and
an external terminal that is connected to the wirings.

7. The light-receiving device of claim 6,
wherein a region of the wirings on the photodiode is formed to be an optical black region as a light shielding film.

8. The light-receiving device of claim 6,
wherein the photodiode includes means which applies a voltage of a value which causes electrical charge multiplication action inside the photodiode.

9. The light-receiving device of claim 6,
wherein the wirings are formed in a grid shape between a plurality of the pixel electrodes.

10. The light-receiving device of claim 6,
wherein the wirings are rewirings.
